(19) United States
(12) Patent Application Publication
(10) Pub. No.: US 2005/0139862 A1
(43) Pub. Date: Jun. 30, 2005

(54) Self-aligned heterojunction bipolar transistor and manufacturing method thereof

(76) Inventors: Chan Woo Park, Daejon (KR); Seung-Yun Lee, Daejon (KR); Shanghoon Kim, Daejon (KR); Jin-Yeong Kang, Daejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/677,665

(22) Filed: Oct. 1, 2003

(30) Foreign Application Priority Data
Nov. 1, 2002 (KR) 2002-67485

(51) Int. Cl. H01L 29/739; H01L 31/0328; H01L 21/331; H01L 31/072

(52) U.S. Cl. 257/197; 438/312

(57) ABSTRACT

Provided are a self-aligned heterojunction bipolar transistor that can prevent electrical short-circuit caused by the agglomeration during the formation of a silicide electrode, minimize resistance by forming thick base electrodes, minimize the parasitic resistance of the base and parasitic capacitance between the base and the collector, and thus improve the process stability and economical efficiency by ruling out a wet-etching process and performing a selective thin film growing process once, and a manufacturing method thereof. The heterojunction bipolar transistor of this research includes: a collector and a collector electrode formed within a silicon substrate; base electrodes formed on the collector and including a protrusion having a first opening and a body having a second opening for exposing the surface of the collector; a base epitaxial layer grown selectively on the collector exposed thorough the first opening; sidewall spacers formed on the sidewalls of the second opening; an emitter electrode formed on the base epitaxial layer in the shape of an overhang that covers the sidewall spacers; and an insulation layer inserted between the overhang of the emitter electrode and the base electrodes and connected to the sidewall spacers.

### FIELD OF THE INVENTION

The present invention relates to a semiconductor device; and, more particularly, to a self-aligned heterojunction bipolar transistor and a manufacturing method thereof.

### DESCRIPTION OF RELATED ART

A very high-speed silicon-germanium (Si—Ge) heterojunction bipolar transistor, which is used in wireless and/or optical communication systems, is a device where the base portion of a silicon homojunction bipolar transistor is substituted with a Si—Ge layer. This uses a property that the energy band gap is decreased gradually as germanium is added to silicon.

When a Si—Ge base epitaxial layer having an energy band gap smaller than those of a silicon emitter and a silicon collector is formed between the silicon emitter and the silicon collector, the conduction band and the valance band become offset in the boundary between the emitter and the base due to the difference of the energy band gaps. Since this offset of the energy bands eases the forward electron-injection from the emitter to the base and obstructs the reverse hole-injection from the base to the emitter, the emitter injection efficiency and current gain are increased. Consequently, the doping level in the base can be raised significantly, without degrading the current gain. The use of heavily doped base increases the maximum oscillation frequency and cut-off frequency of a device and the linearity of the operation of the device, by reducing the resistance and width of the base. It also improves noise characteristics of the device. Meanwhile, if the concentration of germanium is varied gradually with the location in the base, an electric field is formed within the base. Then, the electron mobility is accelerated and the operation speed of the device becomes much faster.

As shown above, since the Si—Ge heterojunction transistor can be manufactured in the conventional silicon semiconductor manufacturing process while bringing about more excellent characteristics, it occupies a competitive position to semiconductor devices using III-V group compounds in the aspects of throughput, reliability, manufacturing cost, noise and economical efficiency. Nowadays, radio frequency (RF) circuits adopting Si—Ge heterojunction transistors are used commercially for the wide ranges of usages and frequencies required in the current wireless communication area and/or optical communication area.

Conventional Si—Ge heterojunction transistors have two types based on their structure: self-aligned ones and non-self-aligned ones. FIGS. 1 to 3 show the examples of the two types.

FIG. 1 is a cross-sectional view illustrating a structure of a conventional self-aligned Si—Ge heterojunction bipolar transistor. Referring to FIG. 1, a method for manufacturing the self-aligned Si—Ge heterojunction bipolar transistor is described herein.

A buried collector 11, a collector 12, a collector electrode 14 and a local silicon oxide layer 13 are formed on a p-silicon substrate 10. Subsequently, a Si—Ge layer base layer 15 is grown thereon. Here, a monocrystalline base epitaxial layer is grown on the collector 12, while a polycrystalline base layer is grown on the local silicon oxide layer 13 and used as a base electrode. Subsequently, a photoresist pattern for defining the base electrode area is formed by using a photolithography process. Then, the polycrystalline base layer in the area other than the base electrode is removed by using the photoresist pattern as an etching mask, and the photoresist pattern is removed. Subsequently, an oxide layer 16 is deposited on the Si—Ge base layer 15 and patterned to form an opening for an emitter-base junction.

Subsequently, a polysilicon layer, which will become an emitter and an emitter electrode, is deposited and patterned to form an emitter electrode 17. The oxide layer 16 is etched to expose the Si—Ge layer 15 by using the emitter electrode 17 as an etching mask. Then, BF₂ is ion-implanted by using the emitter electrode 17 as a mask. The ion-implanted boron (B) forms an external base 18 as it goes through a thermal process. The external base 18 decreases the resistance between the base and the metal base electrode.

Subsequently, after an oxide layer is deposited, spacers 19 on the sidewalls of the emitter electrode 17 is formed by performing anisotropic dry etching. Then, a silicide thin film 20 is formed on the Si—Ge base 15, the emitter electrode 17 and the collector electrode 14 by depositing titanium and performing a thermal treatment. The un-reacted titanium, which is not used in the silicide formation and remains on the spacers 19 and the local silicon oxide layer 13, is removed by performing wet etching. Subsequently, a conventional metal wiring process is performed. The un-described reference numerals 21, 22, 23 and 24 denote an insulation layer, a base terminal, an emitter terminal and a collector terminal, respectively.

The conventional self-aligned Si—Ge heterojunction bipolar transistor as shown in FIG. 1 can form an emitter-base junction by performing self-alignment. Since it uses a low-resistance silicide thin film 20 as an electrode, it has an advantage that it can reduce the contact resistance and the parasitic resistance of the base remarkably.

However, since the base electrode 15 is thin, agglomeration may occur during the formation of the silicide thin film 20. This leads to a problem that the silicide thin film 20 penetrates the base electrode 15 and contacts the collector 12 electrically directly.

FIG. 2 is a cross-sectional view showing a structure of a conventional non-self-aligned Si—Ge heterojunction bipolar transistor. Referring to FIG. 2, a buried collector 31, a collector 32 and a local silicon oxide layer 33 are formed on a p-silicon substrate 30, and a Si—Ge base epitaxial layer 35 are grown thereon. Subsequently, an oxide layer 36 and a nitride layer 37 are deposited sequentially on the Si—Ge base epitaxial layer 35. The oxide layer 36 and nitride layer 37 are patterned to thereby form pad insulation layers 36 and 37. Then, a heavily doped polysilicon layer 38, which will become a base electrode, is deposited. Subsequently, a photoresist pattern that defines the area for emitter-base junction and base electrode is formed through a photolithography process. By using the photoresist pattern as a mask, the Si—Ge base epitaxial layer 35 and the polysilicon layer 38 in the area other than the area for the base electrode are etched, and then the photoresist pattern is removed. Then, an opening is formed in a part for forming an emitter-base junction by etching the polysilicon layer 38 for forming the base electrode to expose a predetermined part of the pad insulation layer 36 and 37 through a photolithography and an etching process.

Subsequently, to isolate the polysilicon layer 38 for forming a base electrode from the emitter electrode 41, an insulation layer 39 is formed by oxidizing the surface of the polysilicon layer 38 for forming a base electrode selectively. Then, a nitride layer is deposited and sidewall spacers 40 are formed by performing anisotropic dry etching. Subsequently, an emitter electrode 41 is formed by etching the pad insulation layers 36 and 37 of the emitter opening to expose the surface of the Si—Ge base epitaxial layer 35, and depositing and patterning polysilicon, which will become an emitter and an emitter electrode. Subsequently, conventional metal wiring process is performed. The un-described reference numerals 42, 43, 44 and 45 denote an insulation layer, a base terminal, an emitter terminal and a collector terminal, respectively.

The conventional non-self-aligned Si—Ge heterojunction bipolar transistor, shown in FIG. 2, has an advantage that it can form a thick base electrode doped in a high concentration. Therefore, it can reduce the resistance between the base electrode and the base terminal greatly and thus improve the noise characteristics in a device without forming a silicide thin film.

However, since the pad insulation layers 36 and 37 should be formed in advance to protect the Si—Ge base epitaxial layer 35 from being damaged during the process for forming sidewall spacers 40, the parasitic resistance of the base in the lower part of the pad insulation layers 36 and 37 and the parasitic capacitance between the base and the collector, which are generated by considering mask misalignment, become increased. Therefore, there is a limit in increasing the operation speed of the device.

FIG. 3 is a cross-sectional view illustrating a structure of a conventional super-self-aligned Si—Ge heterojunction bipolar transistor. Referring to FIG. 3, a buried collector 51, a collector 52, a local silicon oxide layer 53 and a collector electrode 54 are formed on a p-silicon substrate 50, and an oxide layer 55, highly concentrated polysilicon layer 56 for forming a base electrode, and a nitride layer 57 are deposited thereon sequentially. Then, an opening is formed in a part where an emitter-base junction is to be formed by etching the nitride layer 57 and the polysilicon layer 56 for forming a base electrode to expose a predetermined part of the oxide layer 55 through a photolithography and an etching process.

Subsequently, a nitride layer is deposited, and first sidewall spacers 58 are formed by performing anisotropic dry etching. Then, by using the first sidewall spacers 58 and the nitride layer 57 as a mask, the exposed oxide layer 55 is wet-etched to expose the collector 52 under the oxide layer 55. Even after the collector 52 is exposed, the wet etching is continued until an undercut is formed by a predetermined width in the lower part of the highly concentrated polysilicon layer 56 for forming a base electrode. On the surface of the exposed collector 52, a highly concentrated silicon epitaxial layer 59 is grown selectively. Also, in the lower part of the highly concentrated polysilicon layer 56 for forming a base electrode, which is exposed by performing the wet etching and forming the undercut, a polysilicon thin film 60 is grown selectively.

Subsequently, an oxide layer is deposited, and second sidewall spacers 61 are formed over the first sidewall spacers 58 by performing anisotropic dry etching. By using the second sidewall spacers 61 as a mask, the silicon epitaxial layer 59 covering the collector 52 is dry-etched. Then, a Si—Ge base epitaxial layer 62 is grown selectively on the exposed surface of the collector 52. On the Si—Ge base epitaxial layer 62, a silicon emitter epitaxial layer 63 is grown selectively. Subsequently, a polysilicon layer is deposited and patterned to form an emitter electrode 64, and then the conventional metal wiring process is performed. The un-described reference numerals 65, 66, 67 and 68 denote a insulation layer, a base terminal, an emitter terminal and a collector terminal, respectively.

Differently from the conventional method for manufacturing the self-aligned Si—Ge heterojunction bipolar transistor of FIG. 1, the conventional method for manufacturing a super-self-aligned Si—Ge heterojunction bipolar transistor, which is shown in FIG. 3, can form a thick base electrode and thus reduce the resistance of the base electrode and the noise of a device. Also, since it forms the emitter-base and base-collector junction by performing self-alignment, which is different from the conventional method for forming a non-self-aligned Si—Ge heterojunction bipolar transistor, it can reduce parasitic elements, such as the parasitic resistance of the base and the parasitic capacitance between the collector and the base, that are generated by considering the mask misalignment.

However, since the widths of the polysilicon thin film 60 and the silicon epitaxial layer 59 which connect the Si—Ge base epitaxial layer 62 and the polysilicon layer 56 for forming a base electrode are determined by the horizontal undercut which is formed by wet-etching the oxide layer 55, the parasitic capacitance between the collector and the base varies considerably with the width of the undercut. This drops the performance stability of a device. Moreover, since the selective thin film growing process, which is performed several times in the method of FIG. 3, is performed very slowly and the process speed cannot be controlled easily, the economical efficiency and the reproducibility of the process are poor.

### SUMMARY OF THE INVENTION

It is, therefore, an object of the present invention to provide a self-aligned heterojunction bipolar transistor that can minimize resistance and prevent an electrical short circuit, which is caused by agglomeration during the formation of a silicide electrode, by forming a thick base electrode, and a method for manufacturing a self-aligned heterojunction bipolar transistor.

It is another object of the present invention to provide a self-aligned heterojunction bipolar transistor that can minimize the parasitic resistance of the base and the parasitic capacitance between the base and the collector, and improve the process stability and economical efficiency by eliminating wet-etching process and performing a selective thin film growing process once, and a method for manufacturing a self-aligned heterojunction bipolar transistor.

In accordance with an aspect of the present invention, there is provided a heterojunction bipolar transistor, including: a collector and a collector electrode formed within a silicon substrate; base electrodes formed on the collector and including a protrusion having a first opening for exposing the surface of the collector and a body having a second opening for exposing the surface of the collector; a base epitaxial layer grown selectively on the collector exposed through the first opening; sidewall spacers formed on the sidewalls of the second opening and covering the protrusion; an emitter electrode formed on the base epitaxial layer and having a shape of an overhang that covers the sidewall spacers; and an insulation layer inserted between the overhang of the emitter electrode and the base electrodes and connected to the sidewall spacers.

In accordance with another aspect of the present invention, there is provided a method for manufacturing a heterojunction bipolar transistor, including the steps of: a) growing a silicon layer for forming base electrodes on a substrate having a collector, a collector electrode and a local silicon oxide layer; b) depositing an insulation layer on the silicon layer for forming base electrodes; c) forming a groove for forming a collector-base junction by etching the insulation layer and part of the silicon layer for forming base electrodes; d) forming sidewall spacers on the inner walls of the groove; e) forming an opening for exposing the surface of the collector by using the sidewall spacers as a mask and etching the silicon layer for forming base electrodes that remains in the groove; f) growing a base epitaxial layer selectively on the surface of the collector exposed in the opening; g) forming an emitter electrode on the base epitaxial layer; and h) forming base electrodes by patterning the silicon layer for forming base electrodes.

### BRIEF DESCRIPTION OF THE DRAWINGS

The above and other objects and features of the present invention will become apparent from the following description of the preferred embodiments given in conjunction with-the accompanying drawings, in which:

FIG. 1 is a cross-sectional view illustrating a structure of a conventional self-aligned silicon-germanium (Si—Ge) heterojunction bipolar transistor;

FIG. 2 is a cross-sectional view showing a structure of a conventional non-self-aligned Si—Ge heterojunction bipolar transistor;

FIG. 3 is a cross-sectional view illustrating a structure of a conventional super-self-aligned Si—Ge heterojunction bipolar transistor;

FIG. 4 is a cross-sectional view describing a structure of a self-aligned heterojunction bipolar transistor in accordance with an embodiment of the present invention; and

FIGS. 5A to 5G are cross-sectional views describing a method for manufacturing a self-aligned heterojunction bipolar transistor in accordance with an embodiment of the present invention.

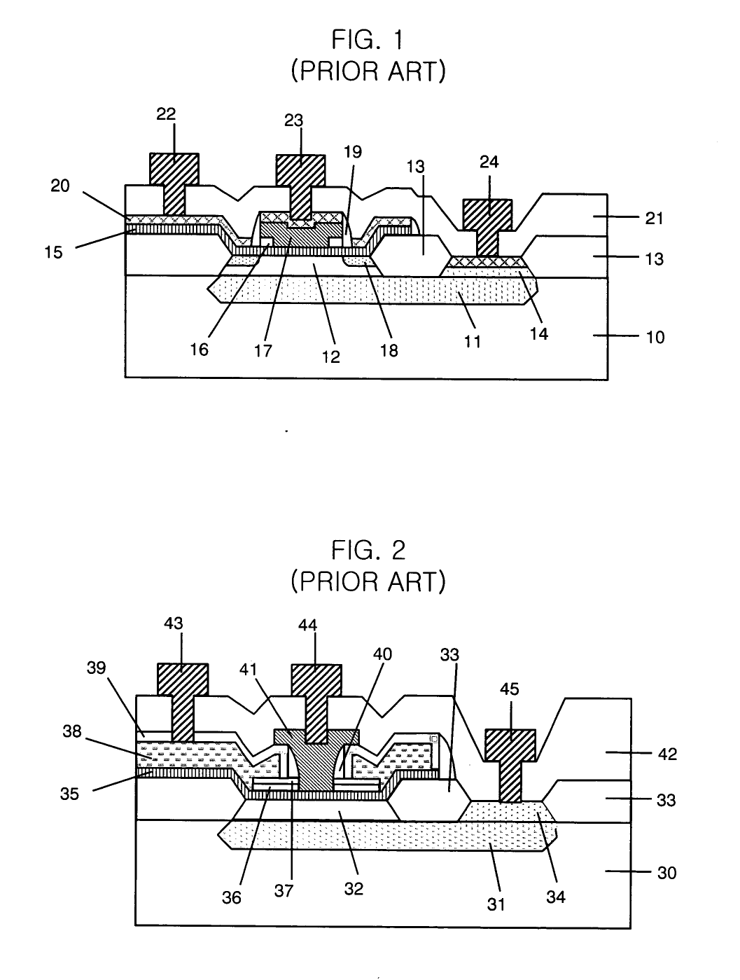

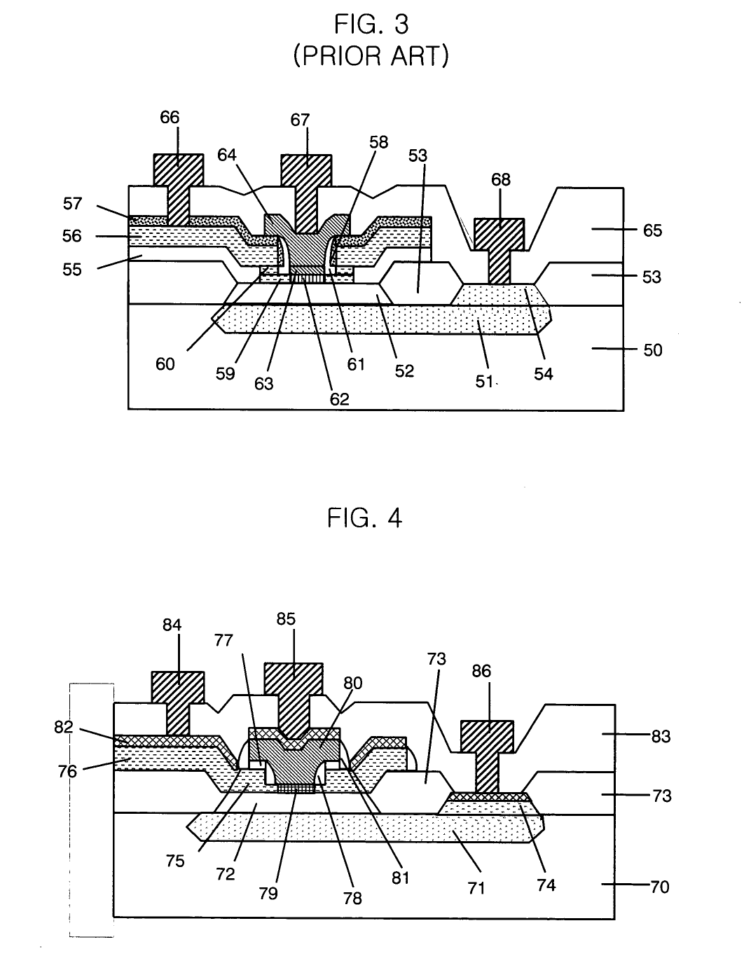

### DETAILED DESCRIPTION OF THE INVENTION

Other objects and aspects of the invention will become apparent from the following description of the embodiments with reference to the accompanying drawings, which is set forth hereinafter.

FIG. 4 shows a cross-sectional view describing a structure of a self-aligned heterojunction bipolar transistor in accordance with an embodiment of the present invention. In the drawing, the self-aligned heterojunction bipolar transistor includes: a p-silicon substrate 70, a collector 72, a collector electrode 74, base electrodes 75 and 76, a base epitaxial layer 79, sidewall spacers 78, an emitter electrode 80, and an insulation layer 77.

The p-silicon substrate 70 includes a buried collector 71 formed by performing ion implantation and a silicon epitaxial layer grown on the buried collector 71. The collector 72 and a collector electrode 74 are isolated from each other by a local silicon oxide layer 73 formed in a predetermined area of the silicon epitaxial layer and connected through the buried collector 71.

The base electrodes 75 and 76 are formed on the collector 72 and include a protrusion having a first opening for exposing the surface of the collector 72 and a body having a second opening for exposing the surfaces of the protrusion and the collector 72 simultaneously. The base epitaxial layer 79 is grown selectively on the exposed collector 72 within the first opening, with sidewall spacers 78 formed on the sidewalls of the second opening and covering the protrusion.

The emitter electrode 80 is formed on the base epitaxial layer in the shape of an overhang covering the sidewall spacers 78. The insulation layer 77 is inserted between the overhang of the emitter electrode 80 and the base electrodes 75 and 76 and connected with the sidewall spacers 78.

In FIG. 4, the base electrodes 75 and 76 are formed by integrating the silicon epitaxial layer 75 on the collector 72 and the polysilicon layer 76 on the local silicon oxide layer 73, and the base epitaxial layer 79 is formed of silicon-germanium (Si—Ge) alloy or silicon.

A silicide thin film 82 is formed on the base electrodes 75 and 76, the emitter electrode 80 and the collector 72. To prevent the silicide thin film 82 on the emitter electrode from contacting the base electrodes 75 and 76, insulation spacers 81 are provided to both sidewalls of the emitter electrode 80 meeting with the base electrodes 75 and 76.

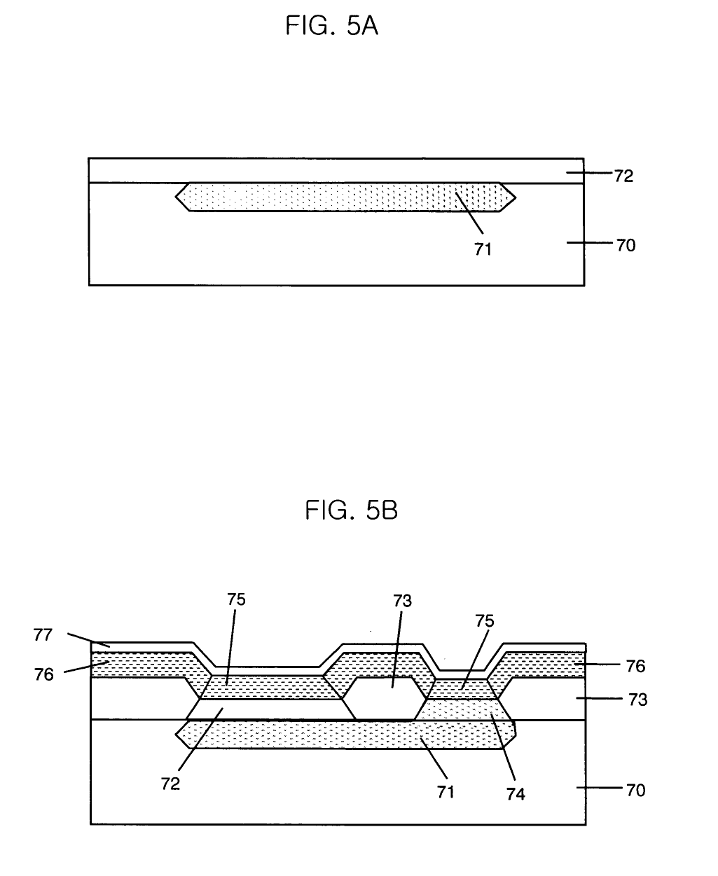

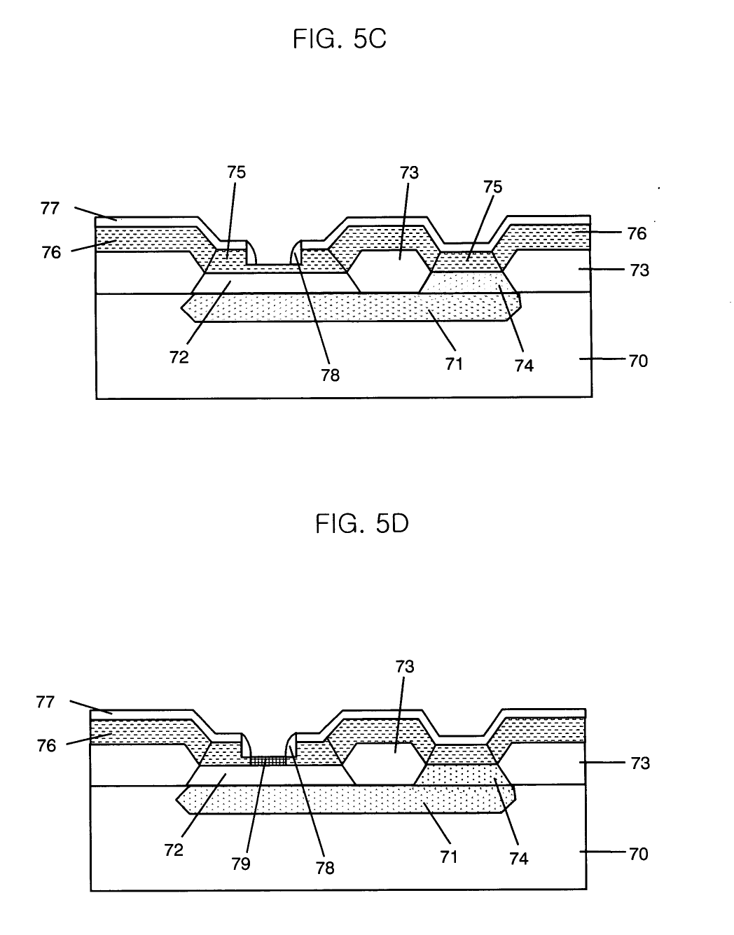

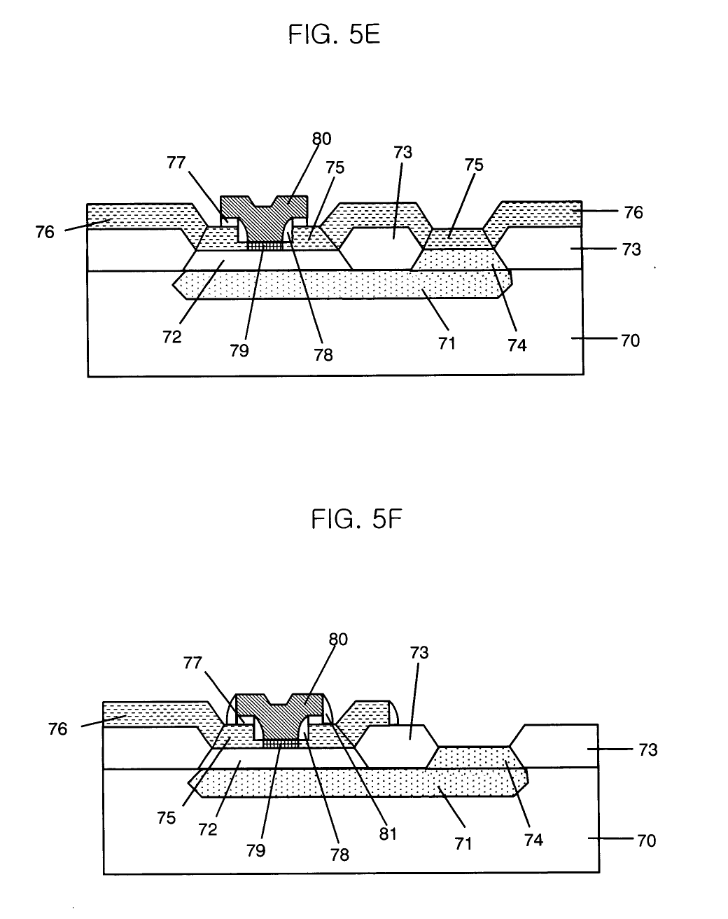

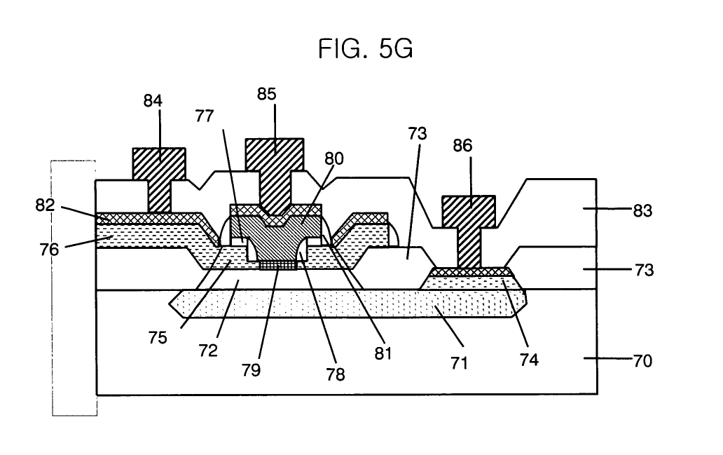

Referring to FIGS. 5A to 5G, which are cross-sectional views describing a method for manufacturing a self-aligned heterojunction bipolar transistor in accordance with an embodiment of the present invention, a heterojunction bipolar transistor is described, herein, using an npn-heterojunction bipolar transistor as an example. However, it is obvious to those skilled in the art that the present invention can be applied to a pnp-heterojunction bipolar transistor, too.

Referring to FIG. 5A, a buried collector 71 is formed by defining an area for forming the buried collector on a p-silicon substrate 70 using a photoresist pattern, ion-implanting n-impurity, such as arsenic (As), and performing a thermal treatment. Subsequently, a collector 72 is formed by growing a collector epitaxial layer without impurity on the p-silicon substrate 70 where the buried collector 71 is formed, and ion-implanting n-impurity, e.g., arsenic (As) and phosphorous (P).

Referring to FIG. 5B, a local silicon oxide layer 73, which is a field oxide layer on the area except the area for forming the collector 72 and a collector electrode 74, which is an active device region, is formed by depositing and patterning a nitride layer (not shown) on the collector 72 and the collector electrode 74, and performing a thermal oxidation. Subsequently, the remaining nitride layer is etched to be removed, and a collector electrode 74 is formed by defining an area for forming the collector electrode 74 and ion-implanting n-impurity. Here, the collector electrode 74 is connected with the buried collector 71.

Subsequently, a p-silicon layer which is used as a base electrode is grown on the entire structure having the collector electrode 74. Here, the process condition is controlled to grow a p-silicon epitaxial layer 75 on the collector 72 and the collector electrode 74, and to grow a p-polysilicon layer 76 on the local silicon oxide layer 73. Subsequently, an insulation layer 77 formed of a nitride layer or an oxide layer is deposited on the p-silicon epitaxial layer 75 and the p-polysilicon layer 76.

Referring to FIG. 5C, a photoresist pattern (not shown) is formed to define an area for forming a base-collector and an emitter-base junction, and then a groove is formed in the area for forming the base-collector and the emitter-base junction by using the photoresist pattern as a mask and etching the entire insulation layer 77 and part of the silicon epitaxial layer 75 sequentially. Subsequently, spacers 78 are formed on the inner sidewalls of the groove by removing the photoresist, depositing the insulation layer formed of an oxide layer or a nitride layer on the entire surface, and performing an anisotropic dry etching on the insulation layer.

Referring to FIG. 5D, the p-silicon epitaxial layer 75 that remains at the bottom of the groove is etched to expose a predetermined part of the collector 72 by using the insulation layer 77 and the spacers 78 as a mask. Subsequently, on the surface of the exposed collector 72, a Si—Ge base epitaxial layer 79 is grown by using a selective epitaxial growth (SEG) method. Here, the thickness of the base epitaxial layer 79 is determined by controlling the growth condition.

Referring to FIG. 5E, an emitter electrode 80 having a shape of an overhang is formed on the base epitaxial layer 79 by depositing an n-polysilicon layer, which will be an emitter electrode, on the entire surface including the base epitaxial layer 79 and patterning it. Subsequently, the insulation 77 is etched to expose the p-polysilicon layer 76 by using the emitter electrode 80 as a mask.

Referring to FIG. 5F, a photoresist pattern (not shown) is formed to define the area for forming base electrodes. Then, by using the photoresist pattern as a mask, the p-polysilicon layer 76 is etched to form base electrodes 75 and 76 which are a thick silicon epitaxial layer 75 and a polysilicon layer 76, respectively. Here, the base electrodes 75 and 76 are formed in the shape of a plate extended over the collector 72 and the local silicon oxide layer 73 simultaneously.

Subsequently, the photoresist pattern for defining the area for forming the base electrodes is removed, and insulation spacers 81 are formed on the sidewalls at the ends of the emitter electrode 80 and the base electrodes 75 and 76 by depositing an oxide layer on the entire surface including the base electrodes 75 and 76 and performing an anisotropic dry etching. The insulation spacers 81 prevent a silicide thin film on the emitter electrode 80, which will be described later on, from contacting the base electrodes 75 and 76, when the silicide thin film is formed. Therefore, if the silicide thin film is not formed, the insulation spacers 81 need not be formed.

Referring to FIG. 5G, a silicide thin film 82 is formed on the base electrodes 75 and 76, the emitter electrode 80 and the collector electrode 74 by depositing a metallic layer, such as titanium (Ti), on the entire surface including the insulation spacers 81 and performing a thermal treatment.

Meanwhile, the conventional self-aligned heterojunction bipolar transistor using a thin Si—Ge base epitaxial layer as base electrodes has a problem that agglomeration is caused during the formation of silicide because the thin film for forming base electrodes is very thin and, as a result, the silicide could contact the collector electrically directly through the base epitaxial layer. However, as illustrated in FIG. 5G, agglomeration does not occur in the self-aligned heterojunction bipolar transistor of the present invention. Therefore, it is possible to improve the operation speed of a device by making the silicide thin film 82 thick as well as increasing the process reliability.

Subsequently, the un-reacted metallic layer, such as titanium, is removed by performing wet etching. Then, a base contact window, an emitter contact window and a collector contact window are formed by depositing an insulation layer 83 on the entire surface of the p-silicon substrate 70 and patterning the insulation layer 83.

Subsequently, a metallic layer is deposited and patterned to form a base terminal 84 for the connection to the polysilicon layer 76 of the base electrodes 75 and 76 through the base contact window, an emitter terminal 85 for the connection to the emitter electrode 80 through the emitter contact window, and a collector terminal for the connection to the collector electrode 74 through the collector contact window.

Although the above embodiment describes an example of a heterojunction bipolar transistor having a silicide thin film 82, the silicide thin film 82 may not be formed. In case where the silicide thin film 82 is not formed, the sidewall spacers 81 need not be formed, either.

As described above, since the technology of the present invention can form a thick base electrode even without usiNg a pad insulation layer, it can reduce the parasitic resistance of the base and the parasitic capacitance between the base and the collector. Since it forms a thick base electrode, it can prevent the short circuit between the base and the collector, which used to be caused by the agglomeration of silicide in the conventional technologies. As a result, the operation speed of a device can be improved by forming the silicide thick, and the process reliability can be improved remarkably. In addition, the technology of the present invention can improve the process stability and the economical efficiency by eliminating wet-etching from a process of defining an area for forming a base-collector junction and performing a selective thin film growth process once.

While the present invention has been described with respect to certain preferred embodiments, it will be apparent to those skilled in the art that various changes and modifications may be made without departing from the scope of the invention as defined in the following claims.

1. A heterojunction bipolar transistor, comprising:
a collector and a collector electrode formed within a silicon substrate;
base electrodes formed on the collector and including a protrusion having a first opening for exposing the surface of the collector and a body having a second opening for exposing the surface of the collector;
a base epitaxial layer grown selectively on the collector exposed through the first opening;
sidewall spacers formed on the sidewalls of the second opening and covering the protrusion;
an emitter electrode formed on the base epitaxial layer and having a shape of an overhang that covers the sidewall spacers; and
an insulation layer inserted between the overhang of the emitter electrode and the base electrodes and connected to the sidewall spacers.

2. The transistor as recited in claim 1, further comprising:
a buried collector area formed within the silicon substrate;
a collector epitaxial layer formed on the silicon substrate; and
a local silicon oxide layer formed on the collector epitaxial layer,
wherein the base electrodes are formed extended over the local silicon oxide layer and part of the collector, and the collector and the collector electrode are connected to each other through the buried collector area.

3. The transistor as recited in claim 1, wherein the base electrode is formed by integrating the silicon epitaxial layer on the collector and the polysilicon layer on the local silicon oxide layer.

4. The transistor as recited in claim 1, wherein the base epitaxial layer is formed of silicon-germanium alloy or silicon.

5. The transistor as recited in claim 1, wherein a silicide thin film is formed on the base electrode, the emitter electrode and the collector electrode.

6. The transistor as recited in claim 5, wherein insulation spacers are formed on both sidewalls of the emitter electrode meeting with the base electrodes in order to prevent the silicide thin film on the emitter electrode from contacting the base electrodes.

7. The transistor as recited in claim 1, wherein the sidewall spacers are formed of an oxide layer or a nitride layer, and the insulation layer is formed of an oxide layer.

8. A method for manufacturing a heterojunction bipolar transistor, comprising the steps of:
a) growing a silicon layer for forming base electrodes on a substrate having a collector, a collector electrode and a local silicon oxide layer;
b) depositing an insulation layer on the silicon layer for forming base electrodes;
c) forming a groove for forming a collector-base junction by etching the insulation layer and part of the silicon layer for forming base electrodes;
d) forming sidewall spacers on the inner walls of the groove;
e) forming an opening for exposing the surface of the collector by using the sidewall spacers as a mask and etching the silicon layer for forming base electrodes that remains in the groove;
f) growing a base epitaxial layer selectively on the surface of the collector exposed in the opening; g) forming an emitter electrode on the base epitaxial layer; and
h) forming base electrodes by patterning the silicon layer for forming base electrodes.

9. The method as recited in claim 8, wherein a silicon epitaxial layer is grown on the collector, and a polysilicon layer is grown on the local silicon oxide layer, when the silicon layer for forming base electrodes is grown.

10. The method as recited in claim 8, further comprising the steps of:
i) forming spacers on the sidewalls of the ends of the emitter electrode meeting with the base electrodes; and
j) forming a silicide thin film on the base electrodes, the collector electrode and the emitter electrode, after the formation of the base electrode.

11. The method as recited in claim 8, wherein the step of c) forming the groove includes the steps of:
c1) forming a mask for defining a collector-base junction on the insulation layer; and
c2) etching the insulation layer by using the mask as an etching mask until the silicon layer for forming base electrodes is exposed, and subsequently forming the groove by etching part of the silicon layer for forming the base electrodes.

12. The method as recited in claim 8, wherein the step of g) forming the emitter electrode includes the steps of:
g1) forming a polysilicon layer on the entire surface including the opening;
g2) forming a mask for defining an emitter electrode on the polysilicon layer;
g3) forming the emitter electrode having a shape of an overhang by using the mask as an etching mask and etching the polysilicon layer; and
g4) etching the insulation layer exposed after the formation of the emitter electrode by using the emitter electrode as an etching mask.

13. The method as recited in claim 8, wherein the base epitaxial layer is formed of silicon-germanium alloy or silicon.
